(19) United States
(12) Patent Application Publication
(10) Pub. No.: US 2009/0212420 A1
(43) Pub. Date: Aug. 27, 2009

(54) INTEGRATED CIRCUIT DEVICE AND METHOD FOR FABRICATING SAME

(76) Inventors: Harry Hedler, Germering (DE); Roland Irsigler, Munich (DE); Andreas Wolter, Regensburg (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 12/035,645

(22) Filed: Feb. 22, 2008

(51) Int. Cl. H01L 23/48; H01L 21/56

(52) U.S. Cl. 257/737; 438/127; 257/E23.01; 257/E21.502

(57) ABSTRACT

Fabricating an integrated circuit device includes providing a semiconductor substrate comprising a first surface and a sec-ond surface, forming a wiring layer on the first surface of the semiconductor substrate, providing a circuit chip, and arranging the circuit chip on the wiring layer of the semi-conductor substrate. The fabricating further includes forming an embedding layer on the wiring layer and on the circuit chip, the embedding layer encapsulating the circuit chip, thinning the semiconductor substrate at the second surface after forming the embedding layer, and forming a conductive via in the semiconductor substrate being electrically coupled to the wiring layer and exposed at the second surface of the semiconductor substrate. Moreover, an integrated circuit de-vice is described.

### BACKGROUND OF THE INVENTION

The development of integrated circuit devices is driven by the trends of ever increasing performance in conjunction with miniaturization of the feature sizes. One approach to facilitate these trends is the integration of multiple integrated circuits (ICs), also referred to as semiconductor chips or dies, on a common carrier substrate to form a so-called multi-chip module (MCM). In a module the integrated circuits are packaged in such a way as to enable their use as a single integrated circuit. Packaging of semiconductor chips is for example applied in order to fabricate a so-called system in package (SiP). Such a chip package is configured to perform different functions of an electronic system. A system in package may for example comprise a processor chip and a memory chip which are electrically connected to each other.

The carrier substrate of a conventional multi-chip module, which is also referred to as interposer, provides an in-plane electrical connection or wiring, thereby connecting semiconductor chips which are arranged horizontally alongside one another. A wiring is also used to provide a vertical electrical pathway through the interposer substrate, thereby enabling mounting of the multi-chip module on a further device or substrate. Moreover, the carrier substrate provides mechanical stability of the chip package.

A known carrier substrate which is used in multi-chip modules is a so-called printed circuit board (PCB). A printed circuit board is a laminated carrier substrate which may comprise a multilayer wiring structure inside. By means of a printed circuit board however, only a low to medium interconnection density to semiconductor chips may be achieved. This is due to the core material of the substrate, a polymer, which is not form stable during temperature steps of a fabrication process. As a consequence, a printed circuit board may shrink and warp, in this way limiting an exact positioning of semiconductor chips on top of the substrate surface, i.e. a positioning of contacts of the chips on respective contact areas of the printed circuit board. The provision of smaller interconnection pitches is therefore restricted.

In order to make possible high density interconnections between an integrated circuit and an interposer substrate (including for example a contact-to-contact pitch of less than 100 μm), a silicon interposer substrate may be used in lieu of a printed circuit board of a multi-chip module. In contrast to a printed circuit board, the thermal extension of a silicon interposer matches that of the semiconductor chips, and the interposer may provide a flat and stable surface during packaging. Furthermore, established thin film techniques are available which allow for fabrication of high density and fine pitch in-plane wiring on silicon.

The fabrication of a silicon interposer for a multi-chip module includes, in addition to making a wiring layer on an upper surface of the interposer, forming conductive through connections or vias in the interposer substrate which provide an electrical pathway between the upper and a lower interposer surface. These through connections are also referred to as “through silicon via” (TSV). Producing a conductive via in a silicon interposer includes forming a via hole in the interposer substrate, forming an insulation layer in the via hole, and filling the via hole with a conductive material.

In order to meet the demands of mechanical stability during fabrication and during assembly of integrated circuits in the production of a multi-chip module, a conventional silicon interposer comprises an adequate thickness of for example more than 350 μm. This minimum thickness may result in the formation of conductive vias—substantially generating via holes and filling vias with a conductive material—to be complex and time-consuming, and therefore expensive. As a consequence, the conductive vias are fabricated with a relatively high aspect ratio of depth to width. However, in order to for example achieve a complete filling of the vias without the risk of voids, conventional formation of via holes for conductive vias is performed with a maximum aspect ratio of depth to width of between about 5:1 to 10:1. The limiting aspect ratio together with the aforesaid minimum thickness of the silicon interposer to be “self-carrying” results in a relatively large lateral space demand of a conductive via, and thus in relatively large pitches of the vias.

### BRIEF DESCRIPTION OF THE DRAWINGS

FIG. 1 shows a flow diagram of a method for fabricating an integrated circuit device according to an embodiment.

FIG. 2 shows a flow diagram of a method for fabricating an integrated circuit device according to another embodiment.

FIGS. 3 to 8 show schematic sectional views of a substrate for illustrating steps of a method for fabricating a multi-chip module according to an embodiment.

FIG. 9 shows an enlarged sectional view of a conductive via according to an embodiment.

FIG. 10 shows a schematic sectional view of a multi-chip module according to another embodiment.

FIGS. 11 to 16 show schematic sectional views of a substrate for illustrating steps of a method for fabricating a multi-chip module according to another embodiment.

FIG. 17 shows an enlarged sectional view of a conductive via according to another embodiment.

Various features of implementations will become clear from the following description, taking in conjunction with the accompanying drawings. It is to be noted, however, that the accompanying drawings illustrate selected implementations and are, therefore, not to be considered limiting of the scope of the invention. The present invention may admit other equally effective implementations.

### DETAILED DESCRIPTION OF THE PREFERRED EMBODIMENT

The implementations described in the following relate to an integrated circuit device comprising a semiconductor substrate and a circuit chip arranged on the semiconductor substrate, and to a method of fabricating the same.

One embodiment includes a method of fabricating an integrated circuit device. The method comprises providing a semiconductor substrate comprising a first surface and a second surface, forming a wiring layer on the first surface of the semiconductor substrate, providing a circuit chip, and arranging the circuit chip on the wiring layer of the semiconductor substrate. The method further comprises forming an embedding layer on the wiring layer and on the circuit chip, the embedding layer encapsulating the circuit chip, and thinning the semiconductor substrate at the second surface after forming the embedding layer. The method furthermore comprises forming a conductive via in the semiconductor substrate, the conductive via being electrically coupled to the wiring layer and exposed at the second surface of the semiconductor substrate.

Another embodiment includes an integrated circuit device. The integrated circuit device comprises a semiconductor substrate, the semiconductor substrate comprising a first surface and a second surface and having a thickness of less than 100 μm. The integrated circuit device further comprises a wiring layer on the first surface of the semiconductor substrate, and a conductive via in the semiconductor substrate being electrically coupled to the wiring layer and exposed at the second surface of the semiconductor substrate. The integrated circuit device furthermore comprises a circuit chip arranged on the wiring layer, and an embedding layer on the wiring layer and on the circuit chip, the embedding layer encapsulating the circuit chip.

Yet another embodiment includes a multi-chip module. The multi-chip module comprises an interposer substrate consisting of silicon, the interposer substrate comprising a first surface and a second surface and having a thickness of less than 100 μm. The multi-chip module further comprises a multilayer wiring layer on the first surface of the interposer substrate, the multilayer wiring layer comprising a plurality of contact areas. The multi-chip module further comprises a plurality of conductive vias in the interposer substrate being electrically coupled to the multilayer wiring layer and exposed at the second surface of the semiconductor substrate. Each conductive via comprises a via hole, the via hole having an aspect ratio of depth to width smaller than 1. The multi-chip module further comprises at least two circuit chips arranged on the wiring layer horizontally next to each other and being electrically coupled to each other by means of the multilayer wiring layer. The circuit chips comprise contact bumps protruding from a surface of the circuit chips and being connected to the contact areas of the multilayer wiring layer. The multi-chip module furthermore comprises an embedding layer on the multilayer wiring layer and on the circuit chips, the embedding layer encapsulating the circuit chips.

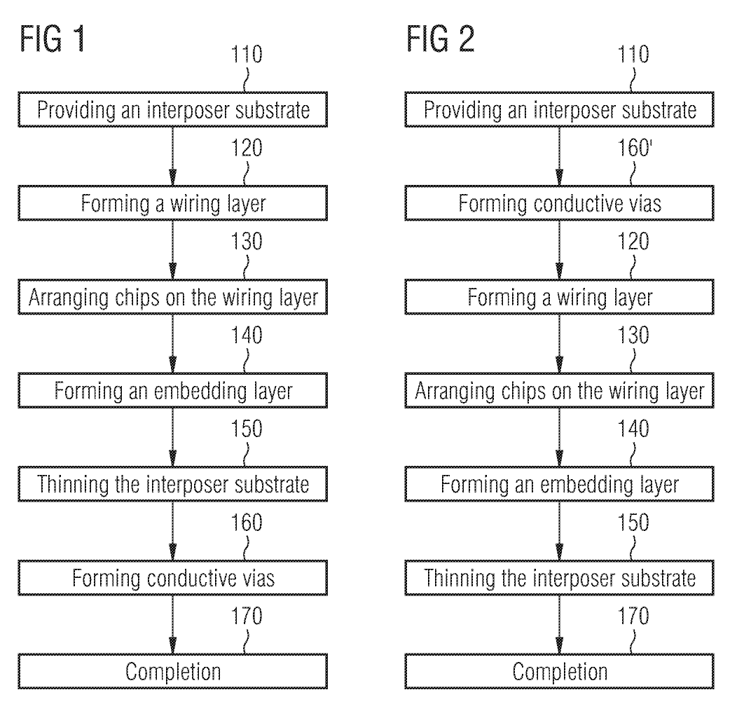

FIG. 1 shows a flow diagram of a method for fabricating an integrated circuit device according to an embodiment. In the method, an interposer substrate and fabrication of the same may be integrated in the process flow instead of handling the interposer as a separate component for chip assembly. The fabricated integrated circuit device may be a multi-chip module including at least two circuit chips. In this context, a circuit chip may comprise a single semiconductor chip or a stack of semiconductor chips arranged on top of and electrically connected to each other. Moreover, a circuit chip may also comprise a passive device or circuit component, respectively, including for example a resistor, a capacitor and/or an inductor.

In a first step 110, a semiconductor substrate may be provided which serves as interposer substrate of the integrated circuit device. The interposer substrate may be a wafer comprising for example silicon and comprises a first and a second surface, which are denoted “upper” and “lower” surface in the following. A wiring layer may be formed on the upper surface of the interposer substrate in a next step 120. The wiring layer provides an in-plane electrical connection on the interposer substrate and comprises a plurality of contact areas for contacting circuit chips. In a further step 130, at least two circuit chips may be arranged horizontally next to each other on the wiring layer. In this step 130, contacts of the circuit chips may be connected to contact areas of the wiring layer.

Following assembly of the circuit chips, an embedding layer may be formed on the wiring layer and on the circuit chips in a step 140. Here, the embedding layer may totally encapsulate the circuit chips. As a consequence, a mechanically stable and stiff structure may be provided above the interposer substrate which may be used for the mechanical stability of the complete integrated circuit device. This feature may be utilized in a subsequent step 150 in order to thin the interposer substrate by removing substrate material at the lower surface.

Subsequently, in a step 160, conductive vias may be formed. The conductive vias may substantially extend between the upper and lower surface of the thinned interposer substrate and may be connected to the wiring layer. Afterwards, further method steps 170 may be performed in order to complete the integrated circuit device. This includes for example applying solder bumps or solder balls on the conductive vias at the lower interposer surface, and performing a wafer singulation or dicing process in order to provide a single integrated circuit device.

Embedding the circuit chips by means of the embedding layer (step 140) may form a mechanical stable structure above the interposer substrate. Therefore, the mechanical carrier function of the interposer substrate may become dispensable for the further method flow. As a consequence, the interposer substrate may be thinned (step 150) to a relatively small thickness of less than 100 μm, for example less than 50 μm. As an example, the thinned interposer substrate may have a thickness of about 40 μm, 30 μm, 20 μm or 10 μm. The conductive vias are therefore formed (step 160) having a corresponding small depth, thus allowing for a simple and time-efficient fabrication. Moreover, due to the small depth the conductive vias may be formed with a low aspect ratio of depth to width, and having a relatively small via-to-via pitch. The aspect ratio may for example be smaller than 1.

FIG. 2 shows a flow diagram of a method for fabricating an integrated circuit device or multi-chip module, respectively according to another embodiment. This method, which integrates an interposer substrate in the process flow as well, includes method steps corresponding to those of the method illustrated in FIG. 1. However, the formation of conductive vias (step 160′) may be carried out in an earlier process stage, i.e. after provision of the interposer substrate (step 110) and prior to formation of the wiring layer (step 120). At this, the conductive vias may be formed in the interposer substrate extending from the upper surface to a predefined depth in the interposer substrate. The subsequent formation of the wiring layer on the upper interposer surface (step 120) may include connecting the wiring layer to the partially “buried” conductive vias.

Mounting circuit chips on the wiring layer (step 130) and forming an embedding layer which encapsulates the chips (step 140) again may provide a mechanically stable structure above the interposer substrate, so that the interposer substrate may subsequently be thinned (step 150) to a relatively small thickness of less than 100 μm. Thinning the interposer substrate may result in exposing the conductive vias at the lower substrate surface. Following the thinning step 150, the integrated circuit device may be completed (step 170) by for example applying solder balls on the conductive vias at the lower substrate surface and performing a dicing process.

Due to the small thickness of the (later) thinned interposer substrate, the conductive vias may be formed (step 160′) having a small depth which corresponds to the thickness of the thinned interposer, thus again making possible a time-efficient fabrication. Also, the conductive vias may be formed with a low aspect ratio of depth to width (e.g. smaller than 1), and having a relatively small via-to-via pitch.

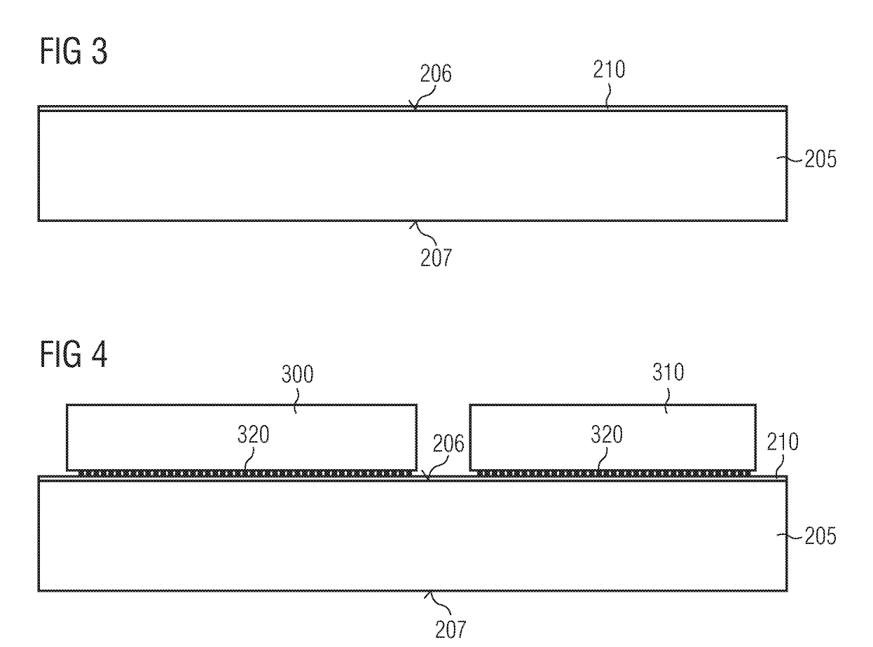

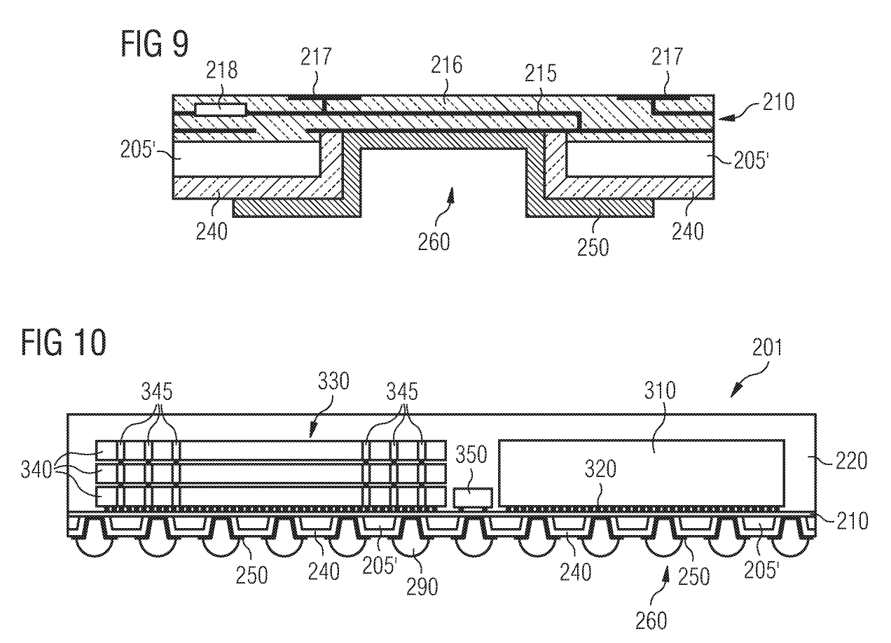

FIGS. 3 to 8 show a schematic sectional view of a substrate for illustrating steps of a method for fabricating a multi-chip module 200 according to an embodiment. The method corresponds to the method flow depicted in FIG. 1. In order to make clear details of the fabrication method, FIG. 9 shows an enlarged view of a conductive via 260 of the multi-chip module 200.

As illustrated in FIG. 3, a bare wafer 205 consisting for example of silicon may be provided according to an embodiment. The wafer 205, which can serve as an interposer substrate in a multi-chip module, may initially have a diameter of for example 300 mm and a relatively large thickness of for example 750 μm. The wafer 205 may comprise an upper surface 206 and a lower surface 207, the upper surface 206 being substantially parallel to the lower surface 207.

A wiring layer 210 may further be formed on the upper surface 206 in order to provide an in-plane (“horizontal”) electrical connection. The wiring layer 210, which is also referred to as “redistribution layer” (RDL), may for example comprise a fine line and space structure and provides a high interconnection density. As illustrated in the enlarged sectional view of FIG. 9, the wiring layer 210 may be a multilayer wiring layer comprising a metallic rewiring structure 215 arranged in form of superimposed layers, which may be insulated from each other by means of an insulating material 216. The insulating material 216 may be a low-k dielectric in order to reduce parasitic capacitance and crosstalk effects.

The wiring layer 210 further comprises contact pads 217 being exposed or located at the surface of the wiring layer 210, as indicated in FIG. 9. The contact pads 217 may have a pad-to-pad pitch of less than 100 μm, e.g. of about 10 μm, in order to make possible a high interconnection density to circuit chips. The wiring layer 210 may furthermore comprise at least one passive device 218. The passive device 218, which is also referred to as “integrated passive device” (IPD) or integrated thin film device may for example comprise a resistor, a capacitor and/or an inductor. The passive device 218 may be connected to the rewiring structure 215 of the wiring layer 210. Fabrication of the wiring layer 210 may for example be carried out using a back-end of line (BEOL) or a respective low-k thin-film method.

Subsequently, as illustrated in FIG. 4, semiconductor chips 300, 310 may be mounted on the wiring layer 210 according to an embodiment. By means of the wiring layer 210, the applied semiconductor chips 300, 310 may be electrically coupled to each other. The semiconductor chips 300, 310 may include a memory chip 300 and a non-memory chip 310 in order to form a system in package. The non-memory chip 310 may for example be a central processing unit (CPU) circuit, a signal processing circuit, or a logic circuit. Both semiconductor chips 300, 310 comprise contact bumps 320 protruding from one face of the chips 300, 310. In this way the semiconductor chips 300, 310 may be mounted on the wiring layer 210 in a flip-chip manner.

In one embodiment, the bumps 320 of the semiconductor chips 300, 310 may be solder bumps which are formed on the chips 300, 310 by means of e.g. an electroplating process. For mounting the chips 300, 310 on the wiring layer 210, the solder bumps 320 may be placed on respective contact pads 217 of the wiring layer 210 and connected to the contact pads 217 by means of a reflow solder process. Alternatively, in another embodiment, the bumps 320 may for example be so-called stud bumps which are formed on the chips 300, 310 by means of a wire bonding process and connected to the contact pads 217 of the wiring layer 210 by means of solder or conductive adhesive.

Following assembly of the semiconductor chips 300, 310, as illustrated in FIG. 5, an embedding layer 220 may be formed on the wiring layer 210 and on the semiconductor chips 300, 310, whereby the embedding layer 220 may completely be encapsulating the semiconductor chips 300, 310 and covering the surfaces of the same according to an embodiment. The embedding layer 220 may comprise a planar surface, which may be used for suction-holding in subsequent process steps. Formation of the embedding layer 220 may result in providing a mechanically stiff and self-carrying structure on top of the wafer 205.

In one embodiment, formation of the embedding layer 220 may for example be carried out by applying a mold material on the wiring layer 210 and the semiconductor chips 300, 310 in liquid or viscous form, thereby also filling up the space between the chips 300, 310 and the wiring layer 210 and the voids between the bumps 320, respectively. The applied mold material may further be cured and subsequently planarized by means of a polishing process. The mold material may for example comprise a polymer matrix material (e.g. an epoxy or a resin) which is filled with particles, for example silicon particles.

In another embodiment, formation of the embedding layer 220 may optionally include performing an underfill process before application of the mold material. For this purpose, an underfill material (not shown) may be applied on the wiring layer 210 before or after mounting of the semiconductor chips 300, 310, the underfill material filling up the space between the chips 300, 310 and the wiring layer 210. The underfill material may also comprise a polymer matrix material which is filled with a particle compound. In this case the particles of the underfill material may have a smaller size compared to those of the mold material in order to improve filling up voids between the chips 300, 310 and the wiring layer 210 and enclosing the contact bumps 320.

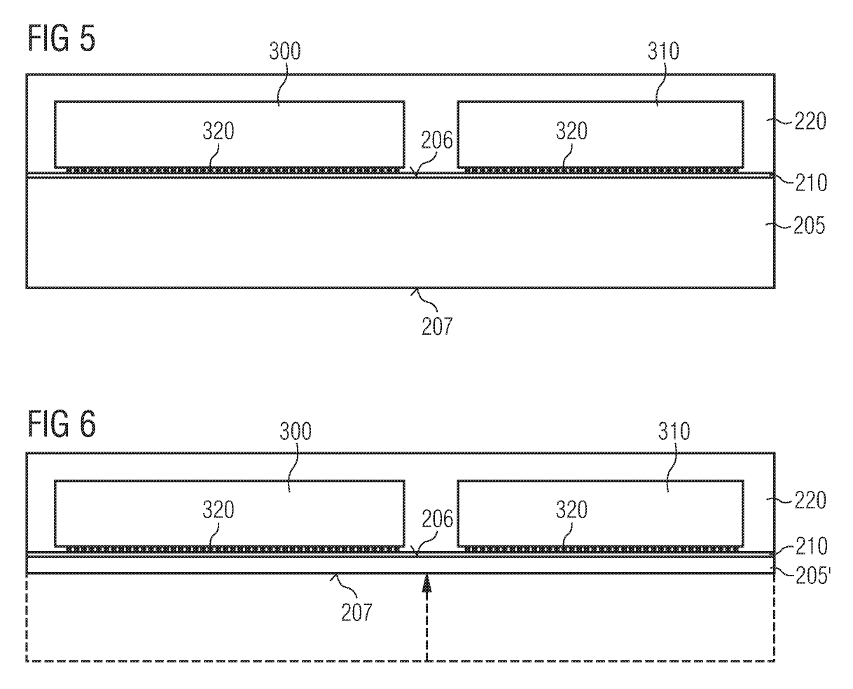

Subsequently, as illustrated in FIG. 6, substrate material may be removed at the lower wafer surface 207 in order to provide a thinned wafer 205′. This step may for example be performed by means of a polishing process like chemical mechanical polishing (CMP). The polishing process may optionally be completed by a wet chemistry or a dry etch process. In the thinning step, the wafer 205 may be thinned to a thickness of less than 100 μm, for example less than 50 μm. The thinned wafer 205′ may e.g. have a thickness of 10 μm. The formation of such a small thickness of the wafer 205′ is made possible because of the mechanical stability achieved by means of the embedding structure on top of the wafer 205′. In other words, the function of the wafer 205′ is substantially limited to providing electrical interconnection, wherein a supporting or self-carrying function is suppressed, according to one embodiment.

In addition to the wiring layer 210 on the upper wafer surface 206 for an in-plane connection, conductive vias 260 (shown in FIG. 9) may be formed in order to provide a vertical electrical pathway through the wafer 205′ and to enable contacting the wiring layer 210 from the lower surface 207. An enlarged view of a potential conductive via 260 is shown in FIG. 9.

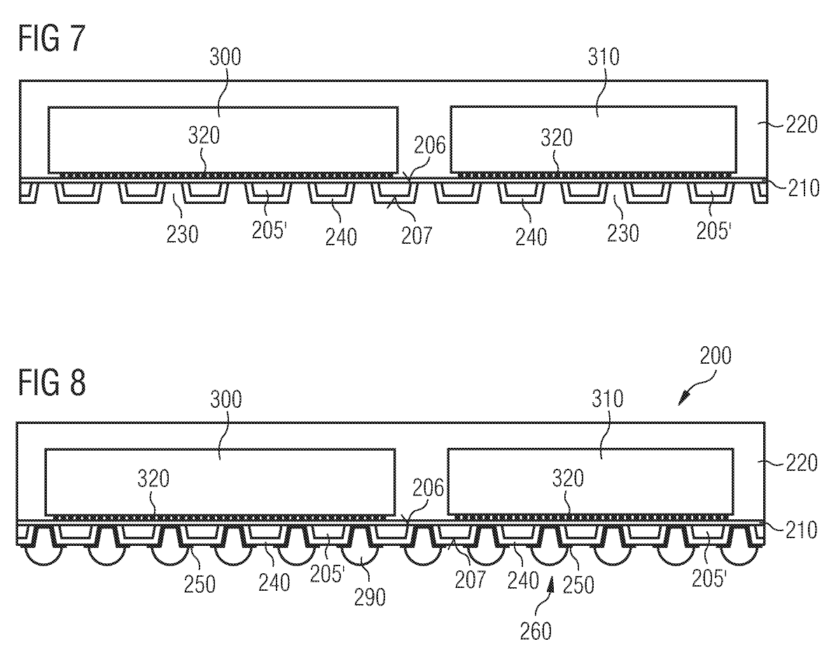

In one embodiment, formation of conductive vias 260 may include, as shown in FIG. 7, forming respective recesses or via holes 230 at the lower surface 207 of the thinned wafer 205′, thereby exposing a portion of the wiring layer 210 and of the wiring structure 215 (shown in FIG. 9) of the wiring layer 210, respectively. Various processes may be performed in order to fabricate the via holes 230. For example, in one embodiment, this includes e.g. performing a laser drilling process. Alternatively, in another embodiment, formation of the via holes 230 may be carried out by means of a dry etching process like e.g. deep reactive ion etching (DRIE). An example is the so-called Bosch process. In the dry etching process, the lateral structure of the via holes 230 may be defined by means of one or several patterned masking layers applied on the lower surface 207 (not shown), which are removed after completing the etching process.

In one embodiment, the wafer 205′ may comprise a relatively small thickness. Therefore, the via hole formation may be carried out in a simple manner and short time. A potential width or diameter of a via hole 230 is for example in the range between 10 and 300 μm. Consequently, for the above specified thickness of the wafer 205′ of for example 10 μm (which corresponds to the depth of a via hole 230), a produced via hole 230 may have a low aspect ratio of depth to width of smaller than 1.

Following the via hole formation, an insulation layer 240 may be formed on sidewalls of the via holes 230 and on the lower surface 207 outside of the via holes 230 as shown in FIG. 7. The insulation layer 240 serves for insulating the conductive vias 260 (shown in FIG. 9), i.e. the conductive portion of the vias 260 from the semiconducting material of the wafer 205′.

Fabrication of the insulation layer 240 may be performed by depositing a respective insulating or dielectric material on the lower surface 207 of the wafer 205′ in a large-area fashion (incl. the via holes 230), and subsequently removing a portion of the insulating material in the via holes to expose a portion of the wiring layer 210. The latter step may e.g. be performed by means of an etching process, including the application of one or several patterned masking layers (not shown).

As a material for the insulation layer 240 for example silicon oxide may be considered. In one embodiment, deposition of silicon oxide may e.g. be carried out by means of a chemical vapor deposition (CVD) process. Here, a low temperature CVD process like e.g. a PECVD process (plasma enhanced CVD) may be performed in order to reduce a temperature induced stress impact on the chips 300, 310. An example is the so-called TEOS process using tetraethyl orthosilicate (TEOS) as source material.

Alternatively, in another embodiment, a low-k dielectric polymer material may be considered for the insulation layer 240. Here a small depth and low aspect ratio of the via holes 230 may enable a relatively large deposition thickness, which is e.g. one or several μm. An example for a polymer material is parylene which may be deposited by means of a CVD process. Moreover other polymer materials like e.g. benzocyclobutene based polymers (BCB) may be considered. Such polymer materials may be applied with a large thickness by means of a spin- or spray-coating process. Both a low k-value and a large thickness of the insulation layer 240 make possible a reduction of parasitic capacitance and crosstalk effects in the conductive vias 260 during operation of the multi-chip module 200.

Furthermore, for completion of the conductive vias 260 (shown in FIG. 9) the via holes 230 are subsequently filled with a conductive material. As illustrated in FIGS. 8 and 9, a conductive layer 250 may be formed in the via holes 230 for this purpose, i.e. on the insulation layer 240 and on the exposed portion of the wiring layer 210 to establish an electrical connection to the conductive structure 215 of the wiring layer 210. The conductive layer 250 may be fabricated to only partially fill a via hole 230, i.e. that the conductive layer 250 comprises an “upside down” U-shaped cross section in the via hole 230, wherein a gap is provided between the portions of the conductive layer 250 formed on the insulation layer 240. The conductive layer 250 of each conductive via 260 may also be formed comprising a portion on the insulation layer 240 outside of the via hole 230, as shown in FIGS. 8 and 9.

In one embodiment, the conductive layer 250 may for example be a metallic layer and may serve as a so-called “under bump metallization” to provide a solder wettable surface. Potential metals for the layer 250 include e.g. Cu, Al, Ni, Au and Ag. The layer 250 may comprise the mentioned materials individually or in the form of material mixes or alloys.

In one embodiment, formation of the conductive layer 250 for the conductive vias 260 may for example be performed by depositing a connected layer 250 in a large-area fashion (e.g. by means of a sputtering process), and subsequently structuring the layer 250 by means of an etching process in order to remove a portion of the layer 250 between the vias 260 (not shown). Alternatively, in another embodiment, formation of the conductive layer 250 may be carried out by means of an electroplating process. Here, a seed layer is deposited in a large area fashion beforehand (e.g. by means of a sputtering process), a structured masking layer (e.g. a photoresist layer) is deposited on the seed layer, followed by electroplating to grow the conductive layer 250 on the seed layer in areas which are not covered by the masking layer. Subsequently the masking layer and the portion of the seed layer which is not covered by the conductive layer 250 are removed (not shown).

Partially filling the via holes 230 by means of the conductive layer 250 may be carried out in a simple manner and short time. In addition, by means of one single conductive layer 250 for a conductive via 260, a relatively short connection pathway to the wiring layer 210 is provided, which is associated with a small transition resistance and therefore a high conductivity of the via 260. In this way it is for example possible to provide a reliable power supply for the non-memory chip 310 via a conductive via 260.

Additionally, as shown in FIG. 8, solder balls 290 may be formed on the conductive layer 250 of the conductive vias 260 at the lower surface 207. Furthermore, a dicing process may be carried out in order to complete and provide the singulated multi-chip module 200. By means of the solder balls 290, the multi-chip module 200 may be further mounted on a substrate, e.g. a printed circuit board (not shown)

FIG. 10 shows a schematic sectional view of a further multi-chip module 201 according to an embodiment. The fabrication and the design of the multi-chip module 201 substantially corresponds to that of the multi-chip module 200 of FIG. 8. Instead of the semiconductor chip 300, the multi-chip module 201 comprises a chip stack 330 including a number of semiconductor chips 340 arranged on top of each other. The semiconductor chips 340 may for example be memory chips.

Each semiconductor chip 340 may comprise a substrate and a plurality of conductive vias 345 extending at least between an upper and a lower substrate surface. By means of the conductive vias 345, the semiconductor chips 340 are electrically connected to each other. At this, the conductive vias 345 of superimposed semiconductor chips 340 may be connected by means of e.g. solder or a conductive adhesive. Correspondingly, also the circuit chip 310 may be a chip stack comprising a number of superimposed semiconductor chips (not shown).

As illustrated in FIG. 10, the multi-chip module 201 may comprise an additional circuit device 350 which may be mounted on the wiring layer 210 and also embedded by the embedding layer 220. The circuit device 350 may be electrically connected to contact pads 217 (shown in FIG. 9) of the wiring layer 210 by means of for example solder or a conductive adhesive. By means of the wiring layer 210, the circuit device 350 may be electrically coupled to the chip stack 330 and/or the semiconductor chip 310. The circuit device 350 may for example be a passive circuit device 350, including for example a resistor, a capacitor and/or an inductor. Instead of one passive circuit device 350, the multi-chip module 201 may comprise several passive devices arranged on the wiring layer 210 and encapsulated by the embedding layer 220 (not shown).

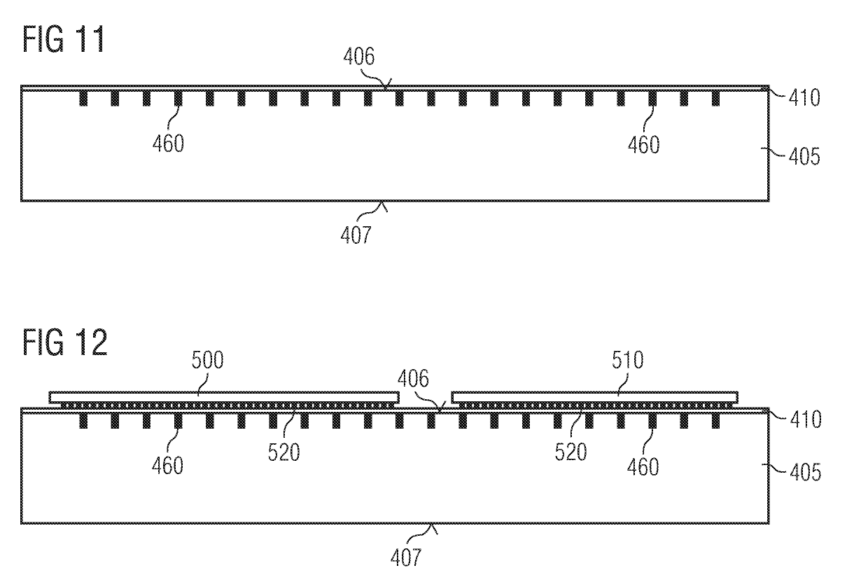

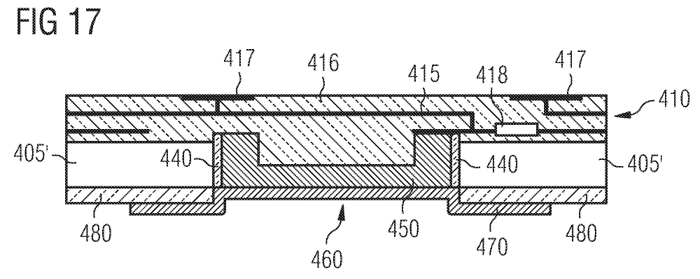

The following FIGS. 11 to 16 show schematic sectional views of a substrate for illustrating steps of a method for fabricating a multi-chip module according to another embodiment. The method corresponds to the method flow depicted in FIG. 2. In order to make clear details of the fabrication method, FIG. 17 shows an enlarged view of a conductive via 460 of multi-chip module 400.

As illustrated in FIG. 11, a wafer 405 consisting for example of silicon may be provided according to an embodiment. The wafer 405 which may serve as interposer substrate in a multi-chip module may initially have a diameter of for example 300 mm and a relatively large thickness of for example 750 μm. The wafer 405 may comprise an upper surface 406 and a lower surface 407 being substantially parallel to each other.

Conductive vias 460 may be formed in the provided wafer 405, the conductive vias 460 extending from the upper surface 406 to a predefined depth in the wafer 405 as shown in FIG. 11. Formation of the partially “buried” conductive vias 460 may include forming respective recesses or via holes at the upper surface 406, forming an insulation layer 440 in the via holes, and filling the via holes with a conductive material or layer 450 (cf. FIG. 17).

In one embodiment, fabrication of the via holes may for example be performed by means of a laser drilling process. Alternatively, in another embodiment, a dry etching process like e.g. a Bosch process may be carried out. At this, the lateral structure of the via holes may be defined by means of one or several patterned masking layers applied on the upper surface 406 (not shown).

As described further below, the wafer 405 may be thinned at the second surface 407 to a relatively small thickness of less than 100 μm (e.g. 10 μm) in a later method stage, thereby exposing the conductive vias 460. As a consequence, the via holes may be fabricated having a small depth which substantially corresponds to the thickness of the thinned wafer 405′ (as shown in FIG. 14). The via hole fabrication may therefore be carried out in a simple manner and short time. The via holes may furthermore be produced having a low aspect ratio of depth to width of smaller than 1. As an example, the width or diameter of a via hole is for example in the range between 10 and 300 μm.

After formation of via holes at the upper surface 406, an insulation layer 440 may be formed in the via holes. The insulation layer 440 may serve for insulating the conductive layer 450 of the vias 460 from the surrounding semiconducting wafer material. In one embodiment, fabrication of the insulation layer 440 may for example be performed by depositing a respective insulating or dielectric material on the upper surface 406 in a large-area fashion, wherein the insulation layer 440 is formed on the sidewalls and on the bottom of the via holes. Here, the deposition may benefit from the small depth and the low aspect ratio of the via holes. The later thinning of the wafer 405 at the lower surface 407 may be carried out in a way that a bottom portion of the insulation layer 440 in the via holes is removed in order to expose the conductive layer 450, wherein the insulation layer 440 remains on the sidewalls of the via holes (cf. FIG. 17).

In embodiment, a material for the insulation layer 440 is for example silicon oxide, which is deposited by means of a CVD process like e.g. the TEOS process. Alternatively, in another embodiment, a low-k dielectric polymer material may be considered for the insulation layer 440, which is applied by means of a CVD process or a spin-coating process. An example are parylene and BCB polymers.

Subsequently, the via holes are filled with a conductive layer 450. The conductive layer 450 may comprise a conductive material like e.g. doped poly Si or C. Furthermore, a metal like e.g. Cu, Al, Ni, Au and Ag may be applied. Further potential materials for the conductive layer 450 include e.g. a solder material or a conductive adhesive. The conductive layer 450 may comprise the mentioned materials individually or in the form of material mixes or alloys. It is also possible to apply sublayers of different materials to form the conductive layer 450.

In on embodiment, fabrication of the conductive layer 450 for the conductive vias 460 may for example be performed by depositing a connected layer 450 in a large-area fashion on the upper surface 406 (e.g. by means of a CVD or a sputtering process), thereby filling the via holes. By means of a subsequent polishing process like for example CMP, the deposited layer 450 may be partially removed so that the layer material remains only in the via holes. Alternatively, in another embodiment, for the case of depositing a metal, an electroplating process may be considered, utilizing a seed layer and a structured masking layer. The electroplating process may be completed by means of a polishing process in order to remove electroplated material outside of the via holes.

The conductive layer 450 may be fabricated to only partially fill a via hole as shown in FIG. 17, i.e. that the conductive layer 450 of a via 460 is formed on the insulation layer 440 at the sides and a bottom area of the via hole, wherein a gap is provided between the portions of the conductive layer 450 covering the insulation layer 440. As a consequence, the conductive layer 450 may comprise a U-shaped cross section. In this way, formation of the conductive layer 450 may be carried out in a simple manner and short time.

After fabrication of the conductive vias 460, a wiring layer 410 is formed on the upper surface 406 of the wafer 405 in order to provide an in-plane electrical connection. The wiring layer 410 may be a multilayer wiring layer comprising a metallic rewiring structure 415 arranged in form of superimposed layers, which are insulated from each other by means of an insulating material 416, e.g. a low-k dielectric, as shown in FIG. 17. The wiring layer 410 adjoins to the conductive vias 460 and is fabricated in a way that the rewiring structure 415 is electrically connected to the conductive layer 450 of the conductive vias 460.

The wiring layer 410 may further comprise contact pads 417 being exposed or located at the surface of the wiring layer 410, as indicated in FIG. 17. The contact pads 417 may have a pad-to-pad pitch of less than 100 μm (e.g. about 10 μm) to make possible a high interconnection density to circuit chips. The wiring layer 410 may furthermore comprise at least one integrated passive device 418, comprising e.g. a resistor, a capacitor and/or an inductor. The passive device 418 may be connected to the rewiring structure 415 of the wiring layer 410. Fabrication of the wiring layer 410 may for example be carried out using a BEOL or a respective low-k thin-film method.

Subsequently, as illustrated in FIG. 12, semiconductor chips 500, 510 are mounted on the wiring layer 410. The semiconductor chips 500, 510, which may have a relatively small thickness, are electrically coupled to each other via the wiring layer 410. The semiconductor chips 500, 510 may include a memory chip 500 and a non-memory chip 510 in order to form a system in package. The non-memory chip 510 may for example be a CPU circuit, a signal processing circuit, or a logic circuit. Both semiconductor chips 500, 510 comprise contact bumps 520 protruding from one face of the chips 500, 510, so that the semiconductor chips 500, 510 may be mounted on the wiring layer 410 in a flip-chip manner.

In one embodiment, the bumps 520 may for example be solder bumps which are formed on the chips 500, 510 by means of e.g. an electroplating process. For mounting the chips 500, 510 on the wiring layer 410, the solder bumps 520 may be placed on respective contact pads 417 (shown in FIG. 17) of the wiring layer 410 and connected to the contact pads 417 by means of a reflow solder process. Alternatively, in another embodiment, the bumps 520 may for example be stud bumps which are formed on the chips 500, 510 by means of a wire bonding process and connected to the contact pads 417 of the wiring layer 410 by means of solder or conductive adhesive.

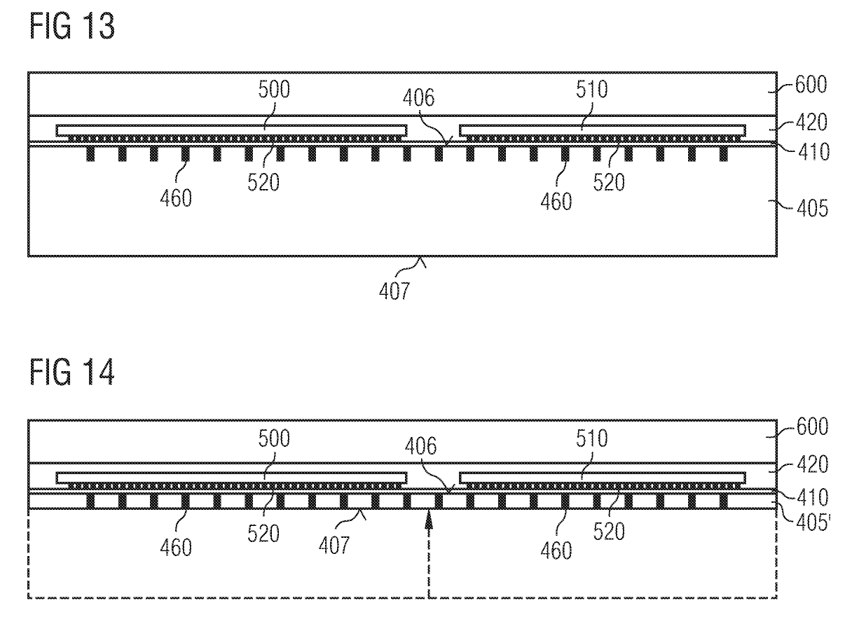

Afterwards, as shown in FIG. 13, an embedding layer 420 may be formed on the wiring layer 410 and on the semiconductor chips 500, 510, the embedding layer 420 completely encapsulating the semiconductor chips 500, 510 and covering a surface of the same according to an embodiment. As further illustrated in FIG. 13, an additional substrate 600, which may comprise e.g. silicon or a metal, may optionally be provided and mounted on the embedding layer 420. By means of the embedding layer 420 and the substrate 600, again a mechanically stiff and self-carrying structure may be provided above the wafer 405. At this, the substrate 600 may provide an enhanced stabilization. Moreover, the substrate 600 may also act as heat spreader in a multi-chip module.

The embedding layer 420 may for example be formed from a polymer foil, which is heated to become liquid or viscous and pressed on the wiring layer 410 and the semiconductor chips 500, 510, thereby also filling up the space between the chips 500, 510 and the wiring layer 410. Here the substrate 600 may be used as a pressing member. It is further possible to optionally perform an underfill process before application of the embedding layer 420 in order to enhance filling up the gap between the chips 500, 510 and the wiring layer 410.

Subsequently, substrate material may be removed at the lower surface 407 of the wafer 405 as illustrated in FIG. 14, thereby providing a thin wafer 405′ and exposing the conductive vias 460, i.e. the conductive layer 450 of the vias 460 at the lower surface 407 according to an embodiment. This step may for example be performed by means of a polishing process like CMP, and may optionally be completed by a wet chemistry or a dry etch process. The wafer 405 may be thinned to a thickness of less than 100 μm, for example less than 50 μm. As an example, the thinned wafer 405′ may e.g. have a thickness of 10 μm. Thinning the wafer 405′ to such a thickness may be possible because of the mechanical stability provided by the embedding structure on top of the wafer 405′, so that a supporting or self-carrying function of the wafer 405′ is dispensable.

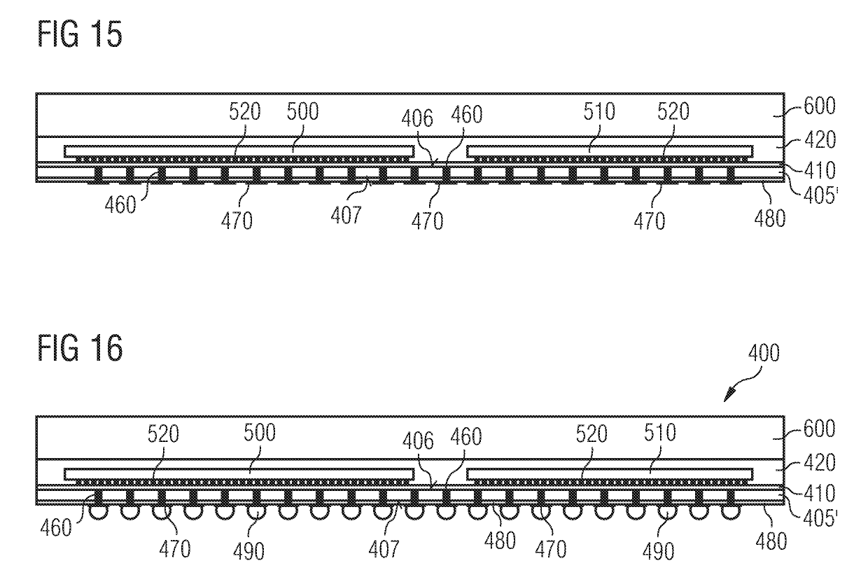

Afterwards, a structured passivation layer 480 is formed at the lower surface 407 providing openings to expose the conductive vias 460 or the conductive layer 450 of the vias 460, respectively, and a structured metallic layer 470 is formed on the conductive layer 450 of the conductive vias 460 and on the passivation layer 480, as illustrated in FIGS. 15 and 17.

The passivation layer 480 may comprise an insulating or dielectric material. An example is a polymer like e.g. parylene or a BCB polymer. In one embodiment, fabricating the passivation layer 480 may e.g. be carried out by applying the passivation layer 480 in a large-area fashion on the lower surface 407 (e.g. by means of a CVD or a spin-coating process), and subsequently structuring the same by means of an etching process. Alternatively, in another embodiment, it may be possible to perform the aforesaid wafer thinning process in a way that the conductive vias 460 protrude from the lower surface 407 (not shown). The passivation layer 480 may again be deposited in a large-area fashion, thereby covering the conductive vias 460, and subsequently the passivation layer 480 may be thinned by means of an etching process so that the vias 460 are exposed.

The subsequently applied metallic layer 470 may serve as “under bump metallization” to provide a solder wettable surface. Potential metals for the layer 470 include e.g. Cu, Al, Ni, Au and Ag. The layer 470 may comprise the mentioned materials individually or in the form of material mixes or alloys. In one embodiment, fabrication of the metallic layer 470 may for example be performed by depositing the layer 470 in a large-area fashion (e.g. by means of a sputtering process), and subsequently structuring the layer 470 by means of an etching process. Alternatively, in another embodiment, an electroplating process may be carried out, utilizing a seed layer and a structured masking layer.

Additionally, as shown in FIG. 16, solder balls 490 may be formed on the metallic layer 470. In addition to providing a solder-wettable surface, the metallic layer 470 may also prevent chemical reactions between the solder balls 490 and the conductive layer 450 of the conductive vias 460. Furthermore, a dicing process may be carried out in order to complete and provide the singulated multi-chip module 400.

The implementations described in conjunction with the drawings are examples. Moreover, further implementations may be realized which comprise further modifications and combinations of the described integrated circuit devices and methods. Instead of the materials indicated for the methods and devices, e.g. other materials may be used. Moreover, the methods are not limited to the fabrication of multi-chip modules comprising two circuit chips arranged horizontally next to each other. The fabrication of an integrated circuit device having only one circuit chip or more than two circuit chips arranged horizontally alongside one another may be performed as well.

With respect to the multi-chip modules 200, 201 of FIGS. 8 and 10, the fabrication of conductive vias may alternatively include filling the via holes with a conductive material or several conductive materials or layers and subsequently applying a metallic layer serving as “under bump metallization” (comparable to the multi-chip module 400 of FIG. 16) instead of applying one single conductive layer 250 according to an embodiment. Moreover, according to another embodiment, the multi-chip modules 200, 201 may comprise an additional substrate on the embedding layer 220 in order to provide an additional backside stabilization and a heat spreader. In this connection, the embedding layer 220 may be formed from a polymer foil as well. Furthermore, the multi-chip module 200 of FIG. 8 may also be provided with at least one additional circuit device which is mounted on the wiring layer 210, comparable to the device 350 of the module 201 of FIG. 10.

With respect to the multi-chip module 400 of FIG. 16, the embedding layer 420 may comprise a mold material, and the substrate 600 may be omitted according to an embodiment. Also, the application of a chip stack comparable to the multi-chip module 201 of FIG. 10 may be considered according to another embodiment. Moreover, according to yet another embodiment, the multi-chip module 400 may additionally comprise at least one additional circuit device which is mounted on the wiring layer 410, comparable to the device 350 of the module 201 of FIG. 10.

Furthermore, the methods may comprise additional process steps provided for the fabrication of an integrated circuit device apart from the described steps. It is e.g. possible to additionally fabricate adhesion and barrier layers for conductive vias. Moreover, process steps may be performed to produce further components of an integrated circuit device.

The preceding description describes examples of implementations of the invention. The features disclosed therein and the claims and the drawings can, therefore, be useful for realizing the invention in its various implementations, both individually and in any combination. While the foregoing is directed to implementations of the invention, other and further implementations of this invention may be devised without departing from the basic scope of the invention, the scope of the present invention being determined by the claims that follow.

What is claimed is:

1. A method of fabricating an integrated circuit device comprising:
providing a semiconductor substrate comprising a first surface and a second surface;
forming a wiring layer on the first surface of the semiconductor substrate;
providing a circuit chip;
arranging the circuit chip on the wiring layer of the semiconductor substrate;
forming an embedding layer on the wiring layer and on the circuit chip, the embedding layer encapsulating the circuit chip;
thinning the semiconductor substrate at the second surface after forming the embedding layer; and
forming a conductive via in the semiconductor substrate being electrically coupled to the wiring layer and exposed at the second surface of the semiconductor substrate.

2. The method according to claim 1, wherein the semiconductor substrate is thinned to a thickness of less than 100 μm.

3. The method according to claim 1, wherein the conductive via comprises a via hole, the via hole having an aspect ratio of depth to width smaller than 1.

4. The method according to claim 1, wherein forming the conductive via comprises:
forming a recess at the second surface of the semiconductor substrate after thinning the semiconductor substrate, the recess exposing a portion of the wiring layer;
forming an insulation layer on sidewalls of the recess; and
forming a conductive layer in the recess being electrically coupled to the wiring layer.

5. The method according to claim 4, wherein the conductive layer is formed on the insulation layer and on the exposed portion of the wiring layer in a manner that a gap is provided between portions of the conductive layer formed on the insulation layer.

6. The method according to claim 5, wherein the insulation layer is further formed covering the second surface of the semiconductor substrate outside of the recess, and wherein the conductive layer is further formed comprising a portion on the insulation layer outside of the recess.

7. The method according claim 1, wherein forming the conductive via comprises:
forming a recess at the first surface of the semiconductor substrate prior to forming the wiring layer;
forming an insulation layer on sidewalls of the recess; and
forming a conductive layer in the recess, wherein the wiring layer is electrically coupled to the conductive layer, and wherein thinning the semiconductor substrate exposes the conductive layer at the second surface of the semiconductor substrate.

8. The method according to claim 7, wherein the conductive layer is formed on the insulation layer at the sides and a bottom area of the recess in a manner that a gap is provided between the portions of the conductive layer formed on the insulation layer.

9. The method according to claim 7, further comprising:
forming a passivation layer on the second surface of the semiconductor substrate after thinning the semiconductor substrate, the passivation layer providing an opening which exposes the conductive layer; and
forming a metallic layer on the conductive layer.

10. The method according to claim 1, wherein the embedding layer is formed having a planar surface.

11. The method according to claim 1, further comprising:
providing an additional substrate; and
arranging the additional substrate on the embedding layer.

12. The method according to claim 1, wherein the circuit chip is provided comprising a contact bump protruding from a surface of the circuit chip, and wherein arranging the circuit chip on the wiring layer comprises connecting the contact bump of the circuit chip to a contact area of the wiring layer.

13. The method according to claim 12, wherein forming the embedding layer further comprises applying an underfill material between the circuit chip and the wiring layer, the underfill material enclosing the bump of the circuit chip.

14. The method according to claim 1, wherein at least two circuit chips are provided, arranged on the wiring layer of the semiconductor substrate horizontally next to each other and encapsulated by the embedding layer, wherein the circuit chips are electrically coupled to each other by means of the wiring layer.

15. The method according to claim 1, further comprising forming a solder ball on the conductive via at the second surface of the semiconductor substrate.

16. An integrated circuit device comprising:
a semiconductor substrate comprising a first surface and a second surface and having a thickness of less than 100 μm;
a wiring layer on the first surface of the semiconductor substrate;
a conductive via in the semiconductor substrate being electrically coupled to the wiring layer and exposed at the second surface of the semiconductor substrate;
a circuit chip arranged on the wiring layer; and
an embedding layer on the wiring layer and on the circuit chip, the embedding layer encapsulating the circuit chip.

17. The integrated circuit device according to claim 16, wherein the conductive via comprises a via hole, the via hole having an aspect ratio of depth to width smaller than 1.

18. The integrated circuit device according to claim 16, wherein the conductive via comprises a via hole, an insulation layer on sidewalls of the via hole, and a conductive layer being electrically coupled to the wiring layer, the conductive layer comprising a U-shaped cross-section in the via hole.

19. The integrated circuit device according to claim 16, further comprising a metallic layer on the conductive layer.

20. The integrated circuit device according to claim 16, further comprising an additional substrate located on the embedding layer.

21. The integrated circuit device according to claim 16, wherein the circuit chip comprises a contact bump protruding from a surface of the circuit chip, the contact bump being connected to a contact area of the wiring layer.

22. The integrated circuit device according to claim 16, wherein the wiring layer is a multilayer wiring layer.

23. The integrated circuit device according to claim 16, wherein the wiring layer comprises an integrated passive device.

24. The integrated circuit device according to claim 16, comprising at least two circuit chips, the circuit chips being arranged on the wiring layer horizontally next to each other, being encapsulated by the embedding layer, and being electrically coupled to each other by means of the wiring layer.

25. The integrated circuit device according to claim 24, wherein the circuit chips include a memory chip and a non-memory chip.

26. The integrated circuit device according to claim 16, further comprising a solder ball on the conductive via at the second surface of the semiconductor substrate.

27. A multi-chip module comprising:
an interposer substrate consisting of silicon, the interposer substrate comprising a first surface and a second surface and having a thickness of less than 100 μm;
a multilayer wiring layer on the first surface of the interposer substrate comprising a plurality of contact areas;
a plurality of conductive vias in the interposer substrate being electrically coupled to the multilayer wiring layer and exposed at the second surface of the interposer substrate, each conductive via comprising a via hole having an aspect ratio of depth to width smaller than 1;
at least two circuit chips arranged on the wiring layer horizontally next to each other and being electrically coupled to each other by means of the wiring layer, the circuit chips comprising contact bumps protruding from a surface of the circuit chips and being connected to the contact areas of the multilayer wiring layer; and
an embedding layer on the multilayer wiring layer and on the circuit chips, the embedding layer encapsulating the circuit chips.
